(19) United States
(12) Patent Application Publication
(10) Pub. No.: US 2026/0164851 A1
(43) Pub. Date: Jun. 11, 2026

(54) METHOD FOR PRODUCING A PLURALITY OF RADIATION-EMITTING SEMICONDUCTOR CHIPS, AND RADIATION-EMITTING SEMICONDUCTOR CHIP

(71) Applicant: ams-OSRAM International GmbH, Regensburg (DE)

(72) Inventor: Martin Rudolph Behringer, Regensburg (DE)

(21) Appl. No.: 18/710,278

(22) PCT Filed: Nov. 15, 2022
(86) PCT No.: PCT/EP2022/081948

§ 371 Date: May 15, 2024

(30) Foreign Application Priority Data
Nov. 16, 2021 (DE) 10 2021 129 843.1

(51) Int. Cl. H10H 20/01; H10H 20/812; H10H 20/821; H10H 20/824

(52) U.S. Cl. CPC H10H 20/013; H10H 20/812; H10H 20/821; H10H 20/824

(57) ABSTRACT

In an embodiment a method includes defining positions for recombination centers, which are designed for radiative recombination of charge carrier pairs, producing the recombination centers at the positions in an active layer and structuring into the semiconductor chips such that at least some of the recombination centers are arranged at a distance from edges of the semiconductor chips, wherein mesa structures and/or steps are generated in a semiconductor layer and/or a growth substrate to define the positions, wherein the positions are located at edges and/or corners of the mesa structures and/or at edges and/or the corners of the steps, and wherein a material for forming the recombination centers has a larger lattice constant than a material in which the mesa structures and/or steps are formed.

### CROSS-REFERENCE TO RELATED APPLICATIONS

This patent application is a national phase filing under section 371 of PCT/EP 2022/081948, filed Nov. 15, 2022, which claims the priority of German patent application 102021129843.1, filed Nov. 16, 2021, each of which is incorporated herein by reference in its entirety.

### TECHNICAL FIELD

The invention relates to a method for producing a plurality of radiation-emitting semiconductor chips. In addition, it relates to a radiation-emitting semiconductor chip.

### SUMMARY

Embodiments provide a method for producing radiation-emitting semiconductor chips which can be operated particularly efficiently. Further embodiments provide radiation-emitting semiconductor chips which can be operated particularly efficiently.

The radiation-emitting semiconductor chips described here are light-emitting diode chips, for example. Electromagnetic radiation is generated in the radiation-emitting semiconductor chips by radiative recombination of charge carrier pairs. In the present case, red light, for example, can be generated by the radiation-emitting semiconductor chips during operation.

According to at least one embodiment of the method, positions for recombination centers are first defined, said recombination centers being designed for radiative recombination of charge carrier pairs. In other words, in a first method step, processes are carried out by which the later positions of recombination centers to be produced can be determined. This definition specifies the positions at which recombination centers for radiative recombination are generated preferentially or with a greater probability than at other positions.

According to at least one embodiment of the method, the method comprises a method step in which recombination centers are produced at the positions in an active layer of the radiation-emitting semiconductor chips. This means that recombination centers are generated at the previously defined positions, for example by epitaxial growth. It is more likely, for example, that the recombination centers are generated at the previously defined positions than at other positions. The recombination centers are generated in an active layer comprising the recombination centers in the completed radiation-emitting semiconductor chips, at or in which the electromagnetic radiation is generated in the completed semiconductor chip by radiative recombination.

According to at least one embodiment of the method, the semiconductor chips are structured in such a way that at least some of the recombination centers are arranged at a distance from the edges of the semiconductor chip.

The radiation-emitting semiconductor chips to be produced have, for example, a radiation exit surface formed by a main surface of the radiation-emitting semiconductor chip.

The directions in which this main surface extends are the lateral directions. Perpendicular to this is the vertical direction, which runs, for example, parallel to a growth direction of the epitaxially produced layers of the radiation-emitting semiconductor chip. In a vertical projection of the recombination centers onto this main surface, the recombination centers are on average closer to a center of gravity of this main surface than to an edge of this main surface. The recombination centers are thus arranged at a distance from the edges of the semiconductor chips.

According to at least one embodiment of the method for producing a plurality of radiation-emitting semiconductor chips, the method comprises the following steps:
defining positions for recombination centers, which are designed for radiative recombination of charge carrier pairs,
producing the recombination centers at the positions in an active layer,
structuring into semiconductor chips, such that at least some of the recombination centers are arranged at a distance from the edges of the semiconductor chips.

In particular, the method described herein can be carried out using the sequence of method steps indicated herein.

The method described here is based on the following considerations, among others. Recombination channels are often generated at the chip edge by structuring into individual semiconductor chips, particularly in the case of radiation-emitting semiconductor chips that emit red light. Charge carriers usually recombine non-radiatively via these channels. For this reason, the efficiency of such radiation-emitting semiconductor chips is relatively poor.

In the production of the radiation-emitting semiconductor chips, positions for recombination centers are first defined, at which the recombination centers are then produced.

In the next step, the semiconductor chips are structured in such a way that the recombination centers are not arranged at the edges of the semiconductor chips.

In this way, it can be achieved that the charge carriers do not recombine at the chip edges but inside the chip, which increases efficiency as non-radiative recombination is suppressed in this way.

The radiation-emitting semiconductor chips described here may in particular be so-called micro-LEDs, which have an edge length of at most 100 μm, in particular of at most 50 μm or of at most 5 μm, and which have a luminous area of less than 0.01 mm², in particular of less than 0.000025 mm².

According to at least one embodiment of the method, mesa structures and/or steps are generated in a semiconductor layer and/or a growth substrate to define the positions, wherein the positions for the recombination centers are located at the edges and/or the corners of the mesa structure.

In particular, the mesa structures have statistically more recombination centers at their edges and/or corners. In other words, the recombination centers are present in higher concentrations at the edges and/or corners of the mesa structures than at other areas of the mesa structures.

The mesa structure is an elevation that has a main surface extending, for example, parallel to the main extension plane of the semiconductor chip to be produced. This main surface is rectangular, for example, within the manufacturing tolerance. It is delimited by the edge of the mesa structure and has four corners, for example.

A material for forming the recombination centers has a larger lattice constant than the material in which the mesa structures and/or steps are formed. This embodiment is based, among other things, on the realization that the material for forming the recombination centers, which has the larger lattice constant, has more space for expansion at the edges and/or corners of the mesa structures and/or steps and is less compressed there. For this reason, the positions defined in this way are energetically more favorable than positions in the middle of the mesa structures and/or steps.

In this way, positions can be defined for the recombination centers at which they are more likely to grow during the production of the recombination centers than at the center of the mesa structures and/or steps. This can be supported by appropriate growth conditions, for example by a high surface mobility and/or reduced growth rates. Increased surface mobility can be generated, for example, by an increased growth temperature.

According to at least one embodiment of the method, the mesa structures and/or steps have a lateral expansion that is smaller than the diffusion length of a material for forming the recombination centers during the production of the recombination centers. The lateral expansion is, for example, the maximum lateral extension of the mesa structure at its main surface.

The diffusion length can be adjusted by selecting the material for forming the recombination centers and the material in which the mesa structures and/or steps are formed, the growth temperature and/or the growth rate or other growth parameters. Since the diffusion length is greater than the maximum lateral expansion of the mesa structures and/or steps, it is possible when producing the recombination centers that the energetically most favorable position for forming the recombination centers is assumed and the recombination centers are more likely to form at the edges of the mesa structures and/or steps than at their center.

According to at least one embodiment of the method, defects in a semiconductor layer and/or a growth substrate are generated or used to define the positions, with the positions being located at the defects. This embodiment is based on the realization that defects that run in a vertical direction or in a lateral direction locally influence the strain field in a semiconductor body. This can result in positions for the incorporation of atoms that are energetically more favorable than other positions. The recombination centers can therefore form at these energetically more favorable positions.

Defect generation and/or defect localization can be supported by electron beam, nanoimprint lithography or other techniques, for example. In this way, the positions for the recombination centers can be defined. In particular, a distance between adjacent defects in the lateral direction is smaller than the diffusion length of the material for forming the recombination centers during the production of the recombination centers. In this way, it can be ensured that the energetically more favorable positions, for example at the defects, are occupied during the formation of the recombination centers.

According to at least one embodiment of the method, the recombination centers are overgrown with at least one further semiconductor layer after their production. In this way, the recombination centers can be embedded in a surrounding semiconductor layer.

According to at least one embodiment of the method, the method comprises the following method steps:
providing a growth substrate,
growing an n-doped semiconductor layer on the growth substrate,
growing an undoped semiconductor layer on the n-doped semiconductor layer,
structuring of mesa structures in the undoped semiconductor layer,
growing an active layer with the recombination centers at the edges and/or corners of the mesa structures,
overgrowing the active layer with the undoped semiconductor layer,
growing a p-doped semiconductor layer on the undoped semiconductor layer,
generating trenches extending through the active layer for structuring into semiconductor chips, such that at least some of the recombination centers are arranged at a distance from the edges of the semiconductor chips.

Alternatively, it is also possible that a p-doped semiconductor layer is grown first, onto which an undoped semiconductor layer is then grown, in which the mesa structures are structured.

The active layer can, for example, comprise a wetting layer on which the recombination centers are subsequently grown. The wetting layer can be formed with the material of the recombination centers. In this case, to grow the recombination centers, for example, a thin wetting layer can first be grown on the mesa structures and the recombination centers are formed on this layer at the edges and/or corners of the mesa structures.

The trenches that extend through the active layer can, for example, extend into the n-doped semiconductor layer or the growth substrate. The trenches laterally completely surround an area which represents the radiation-emitting semiconductor chip to be produced. The trenches are delimited by the edges of the semiconductor chips to be produced, at a distance from which the recombination centers are located.

According to at least one embodiment of the method, the active layer comprises indium, for example in the form of InGaAs or InAs, wherein the indium concentration is greater than 50% at least in places. Parts or all of the arsenic (As) can also be replaced by phosphorus (P). Overall, the semiconductor chip to be produced is then based on an arsenide compound semiconductor material. In this context, this means, for example, that the active layer and/or the growth substrate preferably comprise AlₙGaₘIn₁₋ₙ₋ₘAs, where 0≤n≤1, 0≤m≤1 and n+m≤1. This material does not necessarily have to have a mathematically exact composition according to the above formula. Rather, it can have one or more dopants as well as additional constituents. For the sake of simplicity, however, the above formula only contains the essential constituents of the crystal lattice (Al or As, Ga, In), even if these may be partially replaced by small amounts of other substances.

In addition, a radiation-emitting semiconductor chip is specified. The radiation-emitting semiconductor chip described herein can be produced in particular by a method described herein. All embodiments of the method are also disclosed for the semiconductor chip and vice versa.

According to at least one embodiment, the radiation-emitting semiconductor chip comprises an active region which comprises recombination centers designed for radiative recombination of charge carrier pairs. Furthermore, the semiconductor chip comprises in particular a semiconductor region surrounding the active region in vertical directions. The active region has at least one aperture. The aperture is filled with material of the semiconductor region, and at least some of the recombination centers are arranged at the aperture.

In the manufacture of the radiation-emitting semiconductor chip, the aperture filled with the semiconductor material results from the spacing of neighboring mesa structures, at the edges of which the probability for the arrangement of recombination centers is increased.

In particular, the semiconductor region is undoped and adjoins an n-doped region and a p-doped region of the semiconductor chip.

According to at least one embodiment, the recombination centers are quantum dots or comprise quantum dots. The quantum dots may contain indium and be formed, for example, in the InGaAs or InAs material system. Parts or all of the arsenic (As) can also be replaced by phosphorus (P). The indium concentration in the quantum dots is greater than 50% at least in places. Recombination of charge carriers to form red light can take place in the quantum dots, for example.

According to at least one embodiment, the aperture is formed at a center of the semiconductor chip, wherein recombination centers are arranged around the aperture in the lateral direction.

### BRIEF DESCRIPTION OF THE DRAWINGS

In the following, the method described herein and the optoelectronic semiconductor chip described herein are explained in more detail with reference to exemplary embodiments and the associated figures.

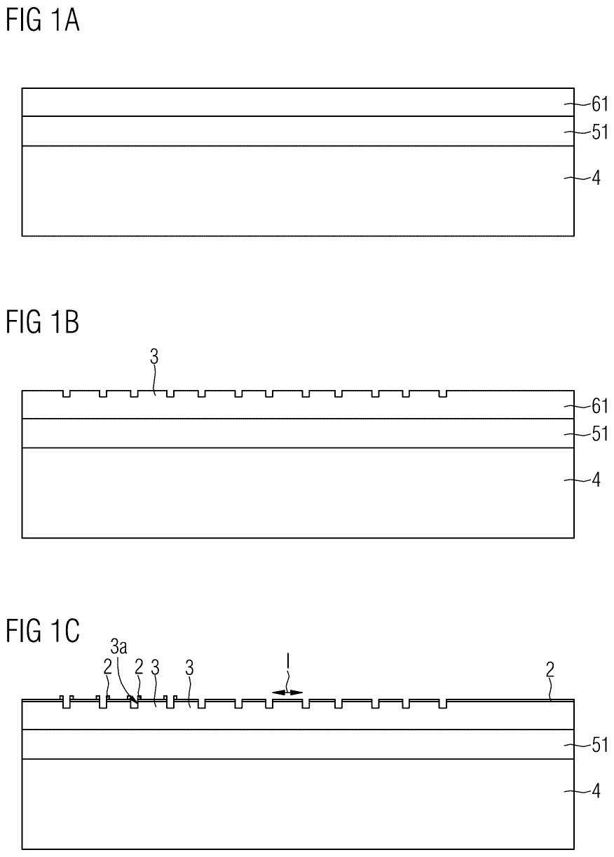

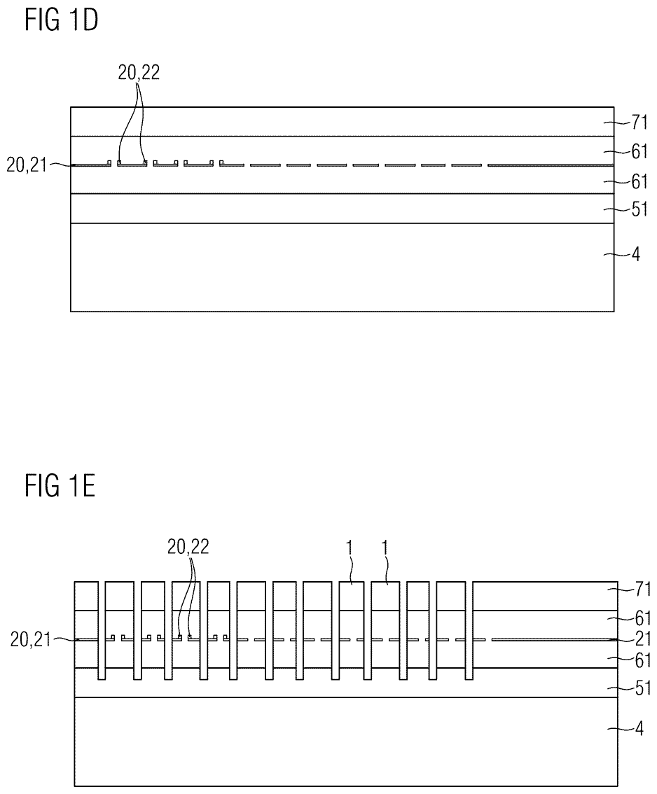

The schematic sectional views of FIGS. 1A to 1E illustrate in more detail an exemplary embodiment of a method;

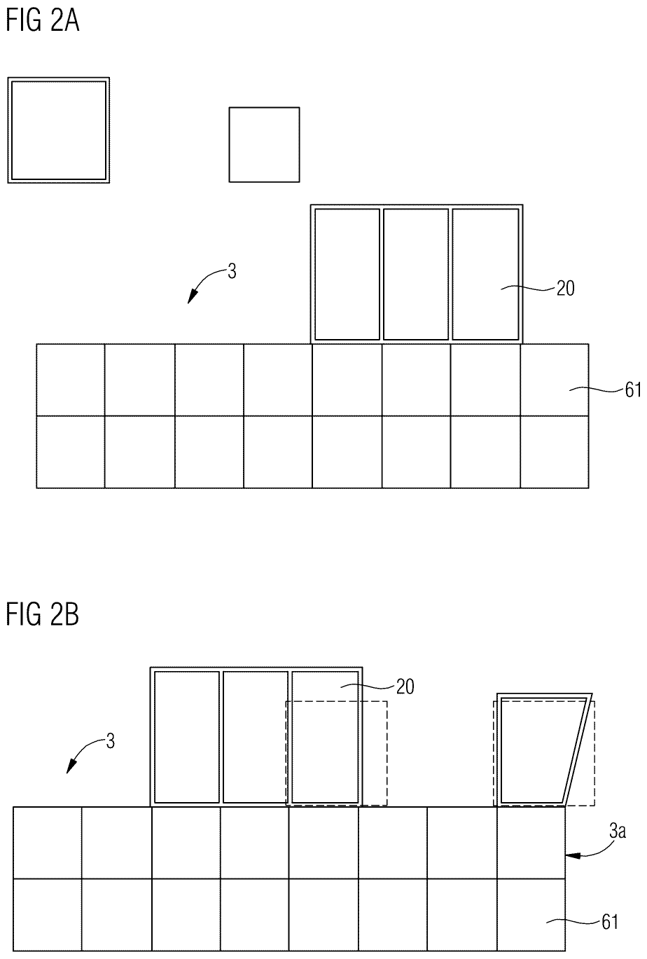

The schematic sectional views of FIGS. 2A and 2B illustrate in more detail a principle for defining the position of recombination centers, as used in an exemplary embodiment of a method;

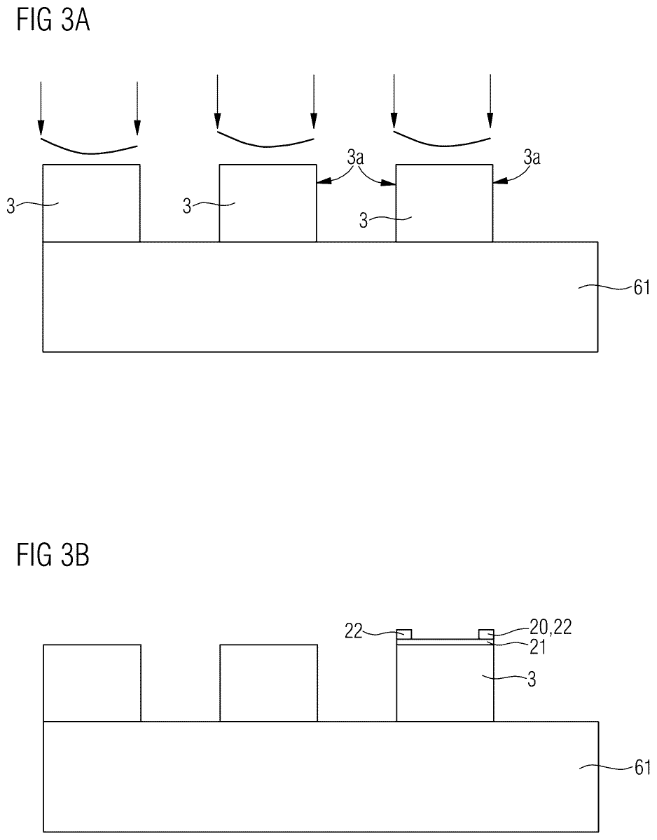

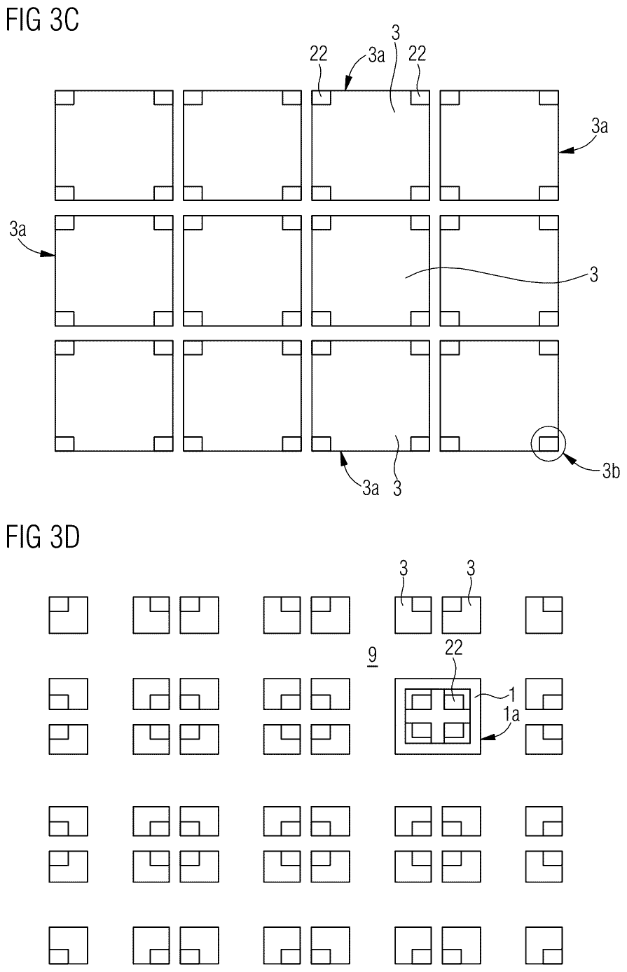

The schematic representations of FIGS. 3A to 3D illustrate in more detail exemplary embodiments of a method;

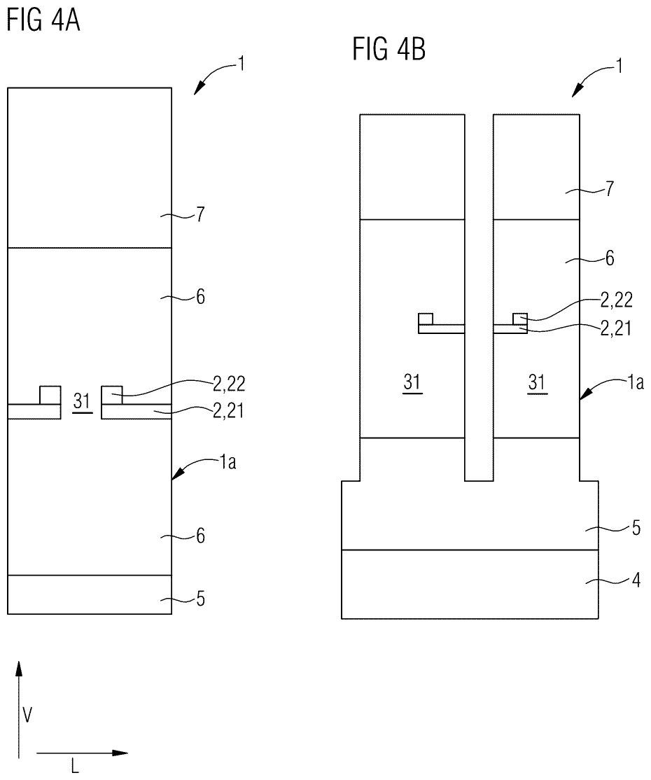

The schematic sectional view of FIGS. 4A and 4B illustrates in more detail exemplary embodiments of a semiconductor chip;

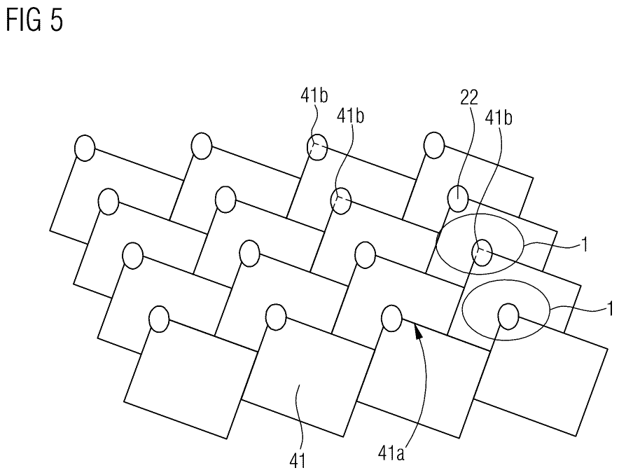

The schematic representation of FIG. 5 illustrates in more detail an exemplary embodiment of a method ; and

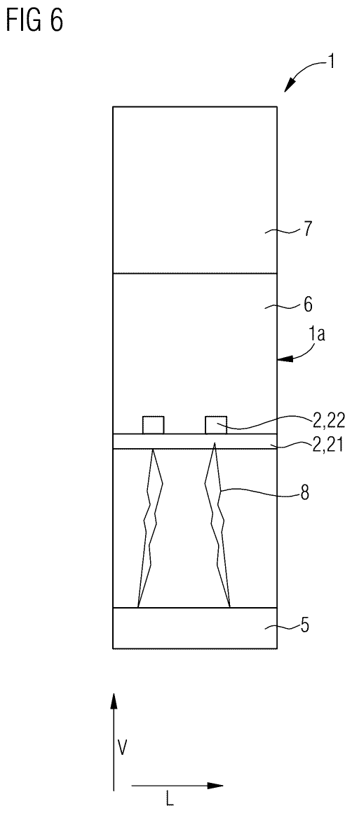

The schematic representation of FIG. 6 illustrates in more detail an exemplary embodiment of a method.

### DETAILED DESCRIPTION OF ILLUSTRATIVE EMBODIMENTS

Elements that are identical, similar or have the same effect are marked with the same reference signs in the figures. The figures and the proportions of the elements shown in the figures are not to be regarded as being to scale. Rather, individual elements may be shown in exaggerated size for better visualization and/or better comprehensibility.

The schematic sectional view of FIGS. 1A to 1E illustrates in more detail a first exemplary embodiment of a method described here. In the method, a plurality of radiation-emitting semiconductor chips 1 are produced.

A growth substrate 4 is first provided for this purpose. In the present case, the growth substrate 4 is a GaAs substrate, for example.

An n-doped semiconductor layer 51 is grown, in particular epitaxially, on the growth substrate 4.

On the side of the n-doped semiconductor layer 51 facing away from the growth substrate 4, an undoped semiconductor layer 61 is grown, in particular epitaxially, FIG. 1A.

In a subsequent method step, FIG. 1B, structuring of mesa structures 3 is performed in the undoped semiconductor layer 61.

This structuring defines positions for recombination centers 22, which are designed for radiative recombination of charge carrier pairs.

These recombination centers 22 are grown in a next method step, FIG. 1C, at these positions-the edges 3a and/or the corners 3b of the mesa structure 3.

The recombination centers 22 are grown in an active layer 20, which comprises, for example, a wetting layer 21 on which the recombination centers 22 are formed. The recombination centers 22 are quantum dots, for example.

The material with which the recombination centers 22 are formed has a larger lattice constant than the material in which the mesa structures 3 are formed. For example, the mesa structures 3 are formed with a semiconductor material such as GaAs or InGaAs, wherein the recombination centers are formed in the InGaAs or InAs material system and the indium concentration in the recombination centers 22 is greater than in the underlying layers 61, 51. Parts or all of the arsenic (As) can also be replaced by phosphorus (P).

The active layer 20 is grown under growth conditions in which the diffusion length of the material for forming the recombination centers 22 is greater than the lateral expansion l of the mesa structures 3. This can be achieved, for example, by a corresponding choice of growth parameters such as growth temperature, growth pressure and growth rate. For example, a wetting layer 21 is initially formed in the active layer 20, and in this wetting layer the recombination centers 22 are formed as thickened regions at the edge 3a and/or in the corners 3b of the mesa structures.

In the subsequent method step, FIG. 1D, the active layer 20, which comprises the recombination centers 22, is overgrown with the undoped semiconductor layer 61. In this way, the recombination centers 22 are embedded in the semiconductor layer 61.

Subsequently, a p-doped semiconductor layer 71 is grown on the undoped semiconductor layer 61, as shown in connection with FIG. 1D.

In the next method step, FIG. 1E, trenches 9 are generated which extend through the active layer 20. The trenches 9 are generated at positions such that at least some of the recombination centers 22 are located at a distance from the edges of the semiconductor chips.

For example, the trenches 9 are generated to extend through the centers of the mesa structures 3 and into the n-doped semiconductor layer 51 or the growth substrate 4, as shown in FIG. 1E.

Subsequently, the growth substrate 4 and a portion of the n-doped layer 51 may be removed to form individual semiconductor chips as described in more detail in connection with FIG. 4.

Alternatively, the semiconductor chips 1 can remain connected to each other and in this way form pixels or image points of a larger, higher-level structure. The edges 1a of the semiconductor chips 1 then represent the edges of the individual pixels. The larger, higher-level structure is then a pixelated semiconductor chip.

In connection with the schematic sectional views of FIGS. 2A and 2B, a principle for defining positions for recombination centers 22 is explained in more detail.

The schematic sectional views of FIGS. 2A and 2B schematically show a mesa structure 3, which is formed with material of the undoped semiconductor layer 61.

Material of the active layer 20 is applied to the mesa structure 3. The mesa structure 3 is formed with GaAs, for example. The active layer 20 is formed with InAs. The active layer 20 therefore has larger molecules than the underlying mesa structure 3. As a result, the active layer 20 grows on the mesa structure 3 under compressive tension.

As shown in FIG. 2B, molecules of the active layer 20 which are arranged at the edge 3a of the mesa structure 3, have an energetically more favorable position, as there is the possibility of strain relief. The dashed line shows the non-tension state with the lowest mechanical energy. At the edge 3a of the mesa structure 3, the deviation from the dashed line is smaller than at the center of the structure.

As shown in connection with the schematic sectional view of FIGS. 3A and 3B, more material is arranged at the edges 3a and/or the corners 3b of the mesa structures 3 during the growth of the active layer 20 with the recombination centers 22 (compare the arrows in FIG. 3A). This leads to a thicker active layer 20 at the edges 3a and/or the corners 3b of the mesa structures 3 and thus to the formation of recombination centers 22, which may be quantum dots. These are increasingly formed at the edges 3a and at the corners 3b of the mesa structures 3. This thicker active layer 20, together with an increased indium concentration, leads to energetically lower energy levels via which radiative recombination is then made possible in these points.

The schematic top view of FIG. 3C shows a top view of the mesa structures 3 with the recombination centers 22 arranged at the corners 3b of the mesa structures 3 near the edges 3a.

The schematic sectional view of FIG. 3D shows the situation after formation of the trenches 9. As can be seen there, the recombination centers 22 for the individual semiconductor chips 1 are located at a distance from the edges 1a of the semiconductor chips 1. Due to the fact that the recombination centers 22 are not arranged at the chip edges 1a, the probability of non-radiative recombination is greatly reduced.

In connection with FIG. 4A, an exemplary embodiment of a semiconductor chip 1 described here is explained in more detail. As shown in FIG. 4B, the semiconductor chip 1 can be monolithically connected to other semiconductor chips of the same design and form a pixel of a higher-level structure.

The radiation-emitting semiconductor chip 1 comprises an active region 2. The active region 2 originates from the active layer 20, which comprises the recombination centers 22. The recombination centers 22 are quantum dots, for example. The radiation-emitting semiconductor chip further comprises a semiconductor region 6, which surrounds the active region in the vertical direction V. The semiconductor region 6 originates from the semiconductor layer 61.

The active region 2 also has an aperture 31 in which the active region 2 is completely filled with the material of the semiconductor region 6. The aperture 31 is formed at a center of the semiconductor chip 1, with recombination centers 22 being arranged around the aperture 31 in the lateral direction L.

In this way, the recombination centers 22 are also embedded in the material of the semiconductor region 6 and surrounded by it on all sides.

At least some of the recombination centers 22 are arranged at the aperture 31. The aperture 31 is the area between neighboring mesa structures 3 during the production of the optoelectronic semiconductor chip 1.

Furthermore, as shown in FIG. 4A, the semiconductor chip may have an n-doped semiconductor region 5 and a p-doped region 7, each of which adjoins the semiconductor region 6, which may be undoped. It is also conceivable that the semiconductor region 6 is lightly doped with one of the two or both dopants or is otherwise made n-type and/or p-type conductive.

The expansion in lateral direction L of the semiconductor chip is in the micrometer range, so that the radiation-emitting semiconductor chip can be a so-called micro-LED.

In connection with FIG. 4B, an exemplary embodiment of a semiconductor chip 1 described here is explained in more detail. In contrast to what is shown in FIG. 4, the semiconductor chip 1 can also be monolithically connected to other semiconductor chips of a similar design and form a pixel of a higher-level structure.

The radiation-emitting semiconductor chip 1 comprises an active region 2. The active region 2 originates from the active layer 20, which comprises the recombination centers 22. The recombination centers 22 are quantum dots, for example. The radiation-emitting semiconductor chip further comprises a semiconductor region 6, which surrounds the active region in the vertical direction V. The semiconductor region 6 originates from the semiconductor layer 61.

The active region 2 also has an aperture 31 in which the active region 2 is completely filled with the material of the semiconductor region 6. In this way, the recombination centers 22 are also embedded in the material of the semiconductor region 6 and surrounded by it on all sides. Unlike in the exemplary embodiment of FIG. 4A, the aperture 31 is formed here at an edge 1a of the semiconductor chip 1. In this way, the distance of at least some of the recombination centers 22 from the edge 1a is particularly large.

In connection with FIG. 5, a further exemplary embodiment of a method described herein is explained in more detail. In this exemplary embodiment, the recombination centers 22 accumulate at the edges 41a and/or corners 41b of steps 41 that have been structured into the substrate 4. The steps 41 can be generated, for example, by an offcut of the substrate 4. Using this method, it is possible, for example, to generate semiconductor chips 1 or pixels that are particularly densely arranged.

In connection with FIG. 6, a further exemplary embodiment of a method described herein is explained in more detail. In this exemplary embodiment, the recombination centers 22 accumulate in the region of defects 9.

This means that, to define the positions for the recombination centers 22, which are quantum dots, for example, defects 9 are generated or used in a semiconductor layer and/or the growth substrate 4, with the positions being located at the defects 9. The defects 9, which run in the vertical direction V and/or in the lateral direction L, locally influence the strain field in the semiconductor layer and/or the growth substrate 4. This can result in positions for the incorporation of atoms that are energetically more favorable than other positions. The recombination centers 22 can therefore form at these energetically more favorable positions.

Defect generation and/or defect localization can be supported by electron beam, nanoimprint lithography or other techniques, for example. In this way, the positions for the recombination centers can be defined. In particular, a distance between adjacent defects 9 in the lateral direction L is smaller than the diffusion length of the material for forming the recombination centers 22 during the production of the recombination centers.

The invention is not restricted to the exemplary embodiments by the description based on these embodiments. Rather, the invention includes any new feature as well as any combination of features, which includes in particular any combination of features in the patent claims, even if this feature or combination itself is not explicitly stated in the claims or exemplary embodiments.

1-14. (canceled)

15. A method for producing a plurality of radiation-emitting semiconductor chips, the method comprising:
defining positions for recombination centers, which are designed for radiative recombination of charge carrier pairs;
producing the recombination centers at the positions in an active layer; and
structuring into the semiconductor chips such that at least some of the recombination centers are arranged at a distance from edges of the semiconductor chips,
wherein mesa structures and/or steps are generated in a semiconductor layer and/or a growth substrate to define the positions,
wherein the positions are located at edges and/or corners of the mesa structures and/or at edges and/or the corners of the steps, and
wherein a material for forming the recombination centers has a larger lattice constant than a material in which the mesa structures and/or steps are formed.

16. The method according to claim 15, wherein the mesa structures and/or steps have a lateral expansion, which is smaller than a diffusion length of the material for forming the recombination centers while producing the recombination centers.

17. The method according to claim 15,
wherein defects of the semiconductor layer and/or the growth substrate are generated or used to define the positions, and
wherein the positions are located at the defects.

18. The method according to claim 15, wherein a distance between adjacent defects in a lateral direction is smaller than a diffusion length of the material for forming the recombination centers while producing the recombination centers.

19. The method according to claim 15, wherein the recombination centers are overgrown with at least one further semiconductor layer after their production.

20. The method according to claim 15,
wherein the active layer comprises indium, and
wherein an indium concentration in the active layer is greater than 50% at least in places.

21. A method for producing a plurality of radiation-emitting semiconductor chips, the method comprising:
providing a growth substrate;
growing an n-doped semiconductor layer on the growth substrate;
growing an undoped semiconductor layer on the n-doped semiconductor layer;
structuring of mesa structures in the undoped semiconductor layer thereby defining positions for recombination centers, which are designed for radiative recombination of charge carrier pairs;
growing an active layer with the recombination centers at edges and/or corners of the mesa structures thereby producing the recombination centers at the positions in the active layer;
overgrowing the active layer with the undoped semiconductor layer;
growing a p-doped semiconductor layer on the undoped semiconductor layer; and
generating trenches extending through the active layer for structuring into semiconductor chips such that at least some of the recombination centers are arranged at a distance from edges of the semiconductor chips.

22. The method according to claim 21,
wherein the active layer comprises indium, and
wherein an indium concentration of the active layer is greater than 50% at least in places.

23. A radiation-emitting semiconductor chip comprising:
an active region of recombination centers designed for radiative recombination of charge carrier pairs; and
a semiconductor region surrounding the active region in a vertical direction,
wherein the active region has an aperture,
wherein the aperture is filled with material of the semiconductor region, and
wherein at least some of the recombination centers are arranged at the aperture.

24. The radiation-emitting semiconductor chip according to the claim 23, wherein the semiconductor region is undoped and adjoins an n-doped region and a p-doped region.

25. The radiation-emitting semiconductor chip according to claim 23,
wherein the active region comprises indium, and
wherein an indium concentration of the active region is greater than 50% at least in places.

26. The radiation-emitting semiconductor chip claim 23,
wherein the aperture is arranged at a center of the radiation-emitting semiconductor chip, and
wherein the recombination centers are arranged around the aperture in a lateral direction.

27. The radiation-emitting semiconductor chip according to claim 23, wherein the recombination centers are or comprise quantum dots.

28. The radiation-emitting semiconductor chip according to claim 23, wherein the radiation-emitting semiconductor chip is a micro-LED.
